(19) United States
(12) Patent Application Publication
(10) Pub. No.: US 2024/0170615 A1
(43) Pub. Date: May 23, 2024

(54) FLIP-CHIP LIGHT-EMITTING DEVICE AND LIGHT EMITTING MODULE HAVING THE SAME

(71) Applicant: TIANJIN SANAN OPTOELECTRONICS CO., LTD., Tianjin (CN)

(72) Inventors: Zhiwei WU, Tianjin (CN); Yanyun WANG, Tianjin (CN); Weiping XIONG, Tianjin (CN); Di GAO, Tianjin (CN); Huan-Shao KUO, Tianjin (CN); Yu-Ren PENG, Tianjin (CN)

(21) Appl. No.: 18/499,798

(22) Filed: Nov. 1, 2023

(30) Foreign Application Priority Data
Nov. 18, 2022 (CN) 202211445114.8

(51) Int. Cl. H01L 33/38; H01L 25/075; H01L 33/10; H01L 33/62

(52) U.S. Cl. CPC H01L 33/382; H01L 25/0753; H01L 33/10; H01L 33/62

(57) ABSTRACT

A flip-chip light-emitting device includes a transparent substrate, an epitaxial structure, a transparent dielectric layer, a plurality of first contact electrodes, multiple second contact electrodes, a metallic reflection layer, a first insulating layer, and an electrode pad region. The epitaxial structure is formed on the transparent substrate, and includes a first type semiconductor layer, an active layer, and a second type semiconductor layer. The first and second contact electrodes are embedded in the transparent dielectric layer, and respectively connected to the first and second type semiconductor layers. The second and first contact electrodes are arranged in an array. The second contact electrodes are disposed in a region perpendicularly below the first pad and are distributed along a circular ring that is concentric with one of the first contact electrodes. A light emitting module includes a circuit board, and the flip-chip light emitting device is mounted on the circuit board.

### CROSS-REFERENCE TO RELATED APPLICATION

This application claims priority to Chinese Invention Patent Application No. 202211445114.8, filed on Nov. 18, 2022, and incorporated by reference herein in its entirety.

### FIELD

The disclosure relates to a light-emitting device and light-emitting module, and more particularly to a flip-chip light-emitting device and a light-emitting module having the flip-chip light-emitting device.

### BACKGROUND

Current spreading is a major factor limiting the development of flip-chip light-emitting devices of a larger size, since the flip-chip design will limit the utilization of an epitaxial layer as a current spreading layer in the conventional flip-chip light-emitting device. When the conventional flip-chip light-emitting device is to be driven by a larger current, an area where light emission occurs will be concentrated near electrodes of the conventional flip-chip light-emitting device and create uneven current spreading, thereby lowering light emission efficiency of the conventional flip-chip light-emitting device.

In view of the above, it is desirable to provide an approach to effectively improve the light emission efficiency of the conventional flip-chip light-emitting device.

### SUMMARY

Therefore, an object of the disclosure is to provide a flip-chip light emitting device and a light emitting module that can alleviate at least one of the drawbacks of the prior art.

The flip-chip light-emitting device includes a transparent substrate, an epitaxial structure, a transparent dielectric layer, a plurality of first contact electrodes, a plurality of second contact electrodes, a metallic reflection layer, a first insulating layer, and an electrode pad region. The epitaxial structure is formed on the transparent substrate that includes a first type semiconductor layer, an active layer, and a second type semiconductor layer sequentially stacked in a laminating direction from an upper surface of the transparent substrate. The transparent dielectric layer is formed on the upper surface of the epitaxial structure. The plurality of first contact electrodes are embedded in the transparent dielectric layer, and electrically connected to the first type semiconductor layer. The plurality of second contact electrodes are embedded in the transparent dielectric layer, and electrically connected to the second type semiconductor layer. The metallic reflection layer is formed on the transparent dielectric layer. The first insulating layer covers the metallic reflection layer and side walls of the epitaxial structure. The electrode pad region is located on the first insulating layer, and includes a first pad that is electrically connected to the first type semiconductor layer, and a second pad that is connected to the second type semiconductor layer. The second contact electrodes and the first contact electrodes are arranged in an array manner. At least some of the second contact electrodes are disposed in a region perpendicularly below the first pad, and are distributed along at least one circular ring that is centered at least one of the first contact electrodes.

The light emitting module includes a circuit board, and the flip-chip light-emitting device is mounted on the circuit board.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic top view illustrating a first embodiment of a flip-chip light-emitting device according to the present disclosure.

FIG. 2 is a schematic cross-sectional view of the embodiment taken from line A-A in FIG. 1.

FIG. 3 is a schematic cross-sectional view of the embodiment taken from line B-B in FIG. 1.

FIG. 4 is a block diagram illustrating a method for making the flip-chip light-emitting device of the first embodiment.

FIGS. 5 to 11 are schematic cross-sectional views illustrating various step in the method for making the flip-chip light-emitting device of the first embodiment.

FIG. 12 is a schematic top view illustrating a second embodiment of the flip-chip light-emitting device according to the present disclosure.

FIG. 13 is a schematic cross-sectional view taken from line C-C in FIG. 12.

FIG. 14 is a schematic cross-sectional view taken from line D-D in FIG. 12.

FIG. 15 to FIG. 19 are schematic cross-sectional views showing various steps in a method for making the flip-chip light-emitting device of the second embodiment.

FIG. 20 is a schematic cross-sectional view illustrating a third embodiment of the flip-chip light-emitting device according to the present disclosure.

FIG. 21 is schematic top view illustrating a light emitting module of a fourth embodiment according to the present disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

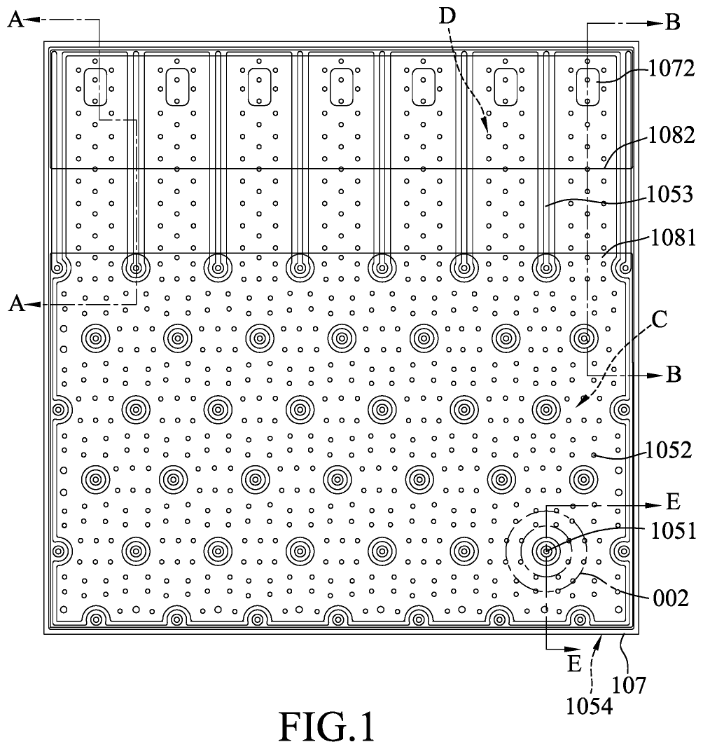

Referring to FIGS. 1 to 3, a flip-chip light-emitting device 100 includes a transparent substrate 101, an epitaxial structure 103, a transparent dielectric layer 104, a plurality of first contact electrodes 1051, a plurality of second contact electrodes 1052, metallic reflection layer 106, a first insulating layer 107, and an electrode pad region. The epitaxial structure 103 is formed on the substrate 101 and includes a first type semiconductor layer 1031, an active layer 1032, and a second type semiconductor layer 1033 sequentially stacked in a laminating direction from an upper surface of the transparent substrate 101. The transparent dielectric layer 104 is formed on the upper surface of the epitaxial structure 103. The metallic reflection layer 106 is formed on the transparent dielectric layer 104. The first insulating layer 107 covers the metallic reflection layer 106 and side walls of the epitaxial structure 103. The electrode pad region is located on the first insulating layer 107, and includes a first pad 1081 that is electrically connected to the first type semiconductor layer 1031, and a second pad 1082 that is connected to the second type semiconductor layer 1033.

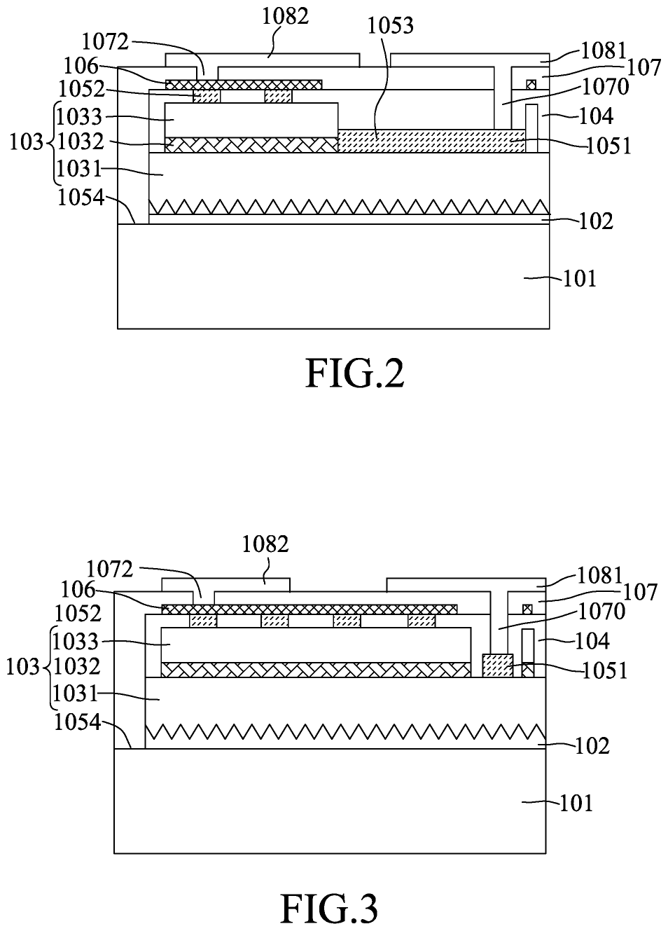

Referring to FIGS. 2 and 3, in this embodiment, the epitaxial structure 103 is made of an AlGaInP compound and emits infrared light.

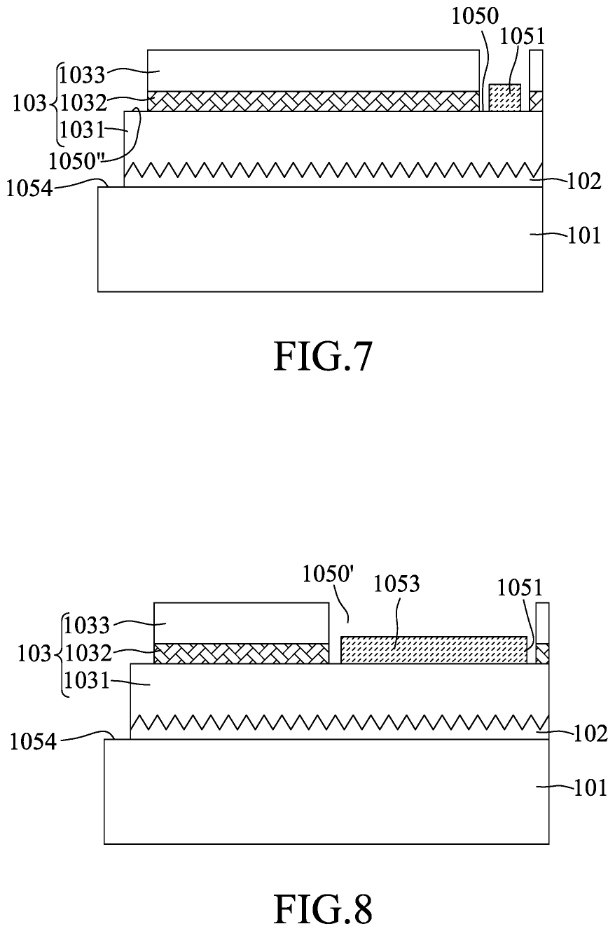

In this embodiment, the transparent dielectric layer 104 is formed on the upper surface and side walls of the epitaxial structure 103. The first contact electrodes 1051, and the second contact electrodes 1052 are embedded in the transparent dielectric layer 104. The first contact electrodes 1051 are electrically connected to the first type semiconductor layer 1031. The second contact electrodes 1052 are electrically connected to the second type semiconductor layer 1033. Referring to FIG. 7, the first contact electrodes 1051 are respectively formed on first mesas 1050 that are formed by etching through the second type semiconductor layer 1033 and the active layer 1032 to expose the first type semiconductor layer 1031. The second contact electrodes 1052 are respectively extending through openings that are formed by etching through the transparent dielectric layer 104 to expose the second type semiconductor layer 1033.

Referring to FIG. 1, the first contact electrodes 1051 and the second contact electrodes 1052 are arranged in an array manner. At least some of the second contact electrodes 1052 are disposed in a region (C) perpendicularly below the first pad 1081 and are distributed along at least one circular ring 002 that is concentric with one of the first contact electrodes 1051. Specifically, the second contact electrodes 1052 disposed in the region (C) perpendicularly below the first pad 1081 are distributed along multiple sets of concentric circular rings 002; each set of the concentric circular rings 002 are centered at one of the first contact electrodes 1051. The first contact electrodes 1051 (i.e., p-type contact electrodes) arranged in the array manner can reduce loss of effective area for light emission due to placement of p-type contact electrodes which can block light. Additionally, contact area between the first contact electrodes 1051 and the first type semiconductor layer 1031 can be reduced to improve current spreading, thereby increasing light emission efficiency. Referring to FIGS. 1 and 2, the first contact electrodes 1051 located in a region (D) perpendicularly below the second pad 1082 are formed as a plurality of fingers 1053. Each of the fingers 1053 extend from the region (D) toward the region (C), and is connected with a corresponding one of the first contact electrodes 1051 located in the region (C). In some embodiments, each of the fingers 1053 are connected to a nearest one of the first electrodes 1051 in the region (C) as shown in FIG. 1. With this configuration of the first electrodes 1051, loss of effective light emitting area may be reduced.

Referring to FIG. 3, the metallic reflection layer 106 is formed on the transparent dielectric layer 104, and electrically connected to the second contact electrodes 1052. The first insulating layer 107 is formed on the metallic reflection layer 106. In some embodiments, the first insulating layer 107 covers the metallic reflection layer 106 and the side walls of the epitaxial structure 103. First openings 1060 (only one is shown in FIG. 3) are formed in the metallic reflection layer 106 above the first contact electrode 1051, and the first insulating layer 107 is filled in the first openings 1060 to isolate the metallic reflection layer 106 from the first pad 1081 that is in ohmic contact with the first contact electrode 1051.

More specifically, the first insulating layer 107 covers the metallic reflection layer 106, exposed areas of the transparent dielectric layer 104, side walls of the metallic reflection layer 106 and the transparent dielectric layer 104, and fills the first openings 1060 of the metallic reflection layer 106, thereby protecting the epitaxial structure 103. Referring to FIG. 3, first through holes 1070 (only one is shown in FIG. 3) pass through the first insulating layer 107 and the transparent dielectric layer 104 at positions where the first openings 1060 are formed in the region (C). The first through holes 1070 expos the first contact electrodes 1051. A plurality of second through holes 1072 are formed in the region (D), pass through the first insulating layer 107, and expose the metallic reflection layer 106. The second pad 1082 is electrically connected to the metallic reflection layer 106 via the second through holes 1072. Referring to FIGS. 1 and 3, the first pad 1081 is formed above the first insulating layer 107, fills the first through holes 1070, is connected with the first contact electrodes 1051, and is thereby electrically connected to the first type semiconductor layer 1031. The second pad 1082 is formed on the first insulating layer 107 and fills the second through holes 1072, to thereby connect with the metallic reflection layer 106. Because the metallic reflection layer 106 is electrically connected to the second contact electrode 1052 in the transparent conducting layer 104, the second pad 1082 is electrically connected to the second type semiconductor layer 1033.

Referring to FIGS. 2 and 3, the flip-chip light-emitting device 100 includes a transparent bonding layer 102 located between the transparent substrate 101 and the epitaxial structure 103. The transparent bonding layer 102 bonds the epitaxial structure 103 to the transparent substrate 101. In some embodiments, the transparent bonding layer 102 may have a patterned surface on the side that bonds with the epitaxial structure 103. In some embodiment, the flip-chip light-emitting device 100 emits red light or infrared light.

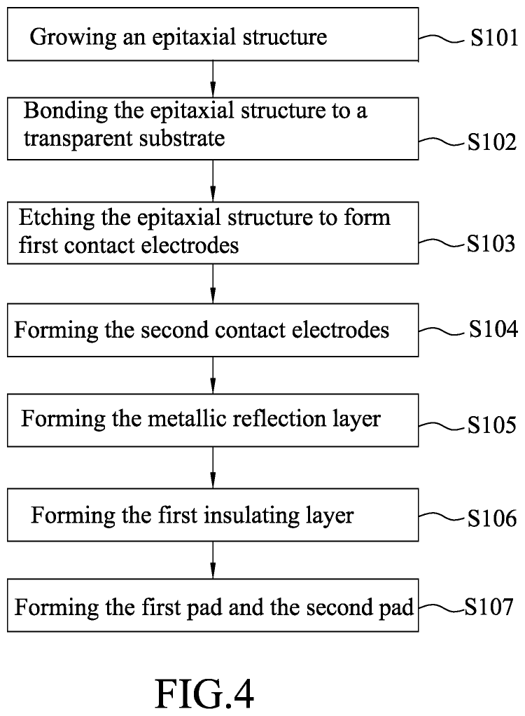

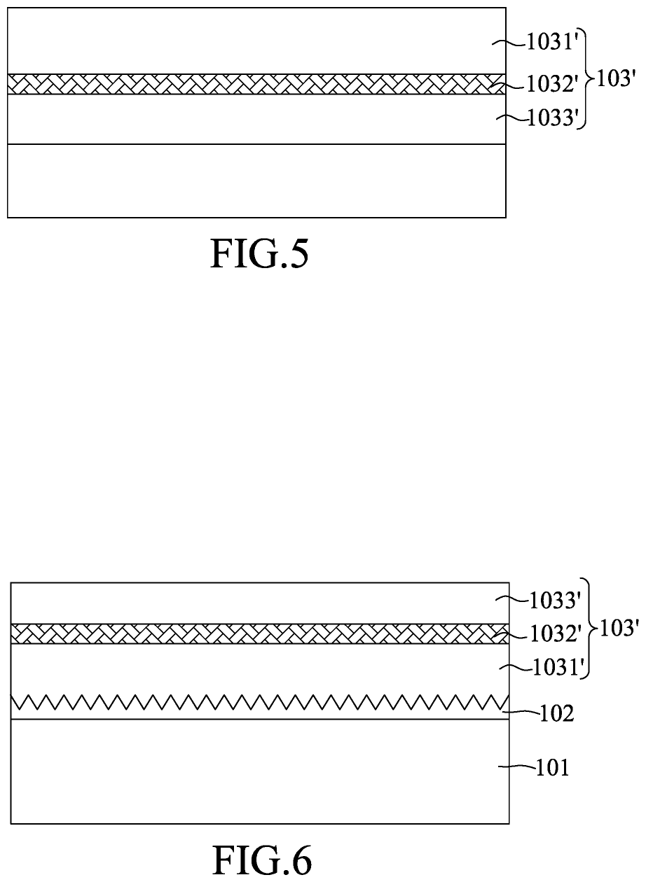

The present disclosure also discloses a method of making the flip-chip light-emitting device 100. Referring to FIG. 4, the method includes steps S101 to S107. Referring to FIG. 5, in the step S101, a second type semiconductor layer 1033′, and an active layer 1032′, and a first type semiconductor layer 1031′ are sequentially grown on a growth substrate 001. The first type semiconductor layer 1031′, the active layer 1032′, and the second type semiconductor layer 1033′ form an epitaxial stack 103′. In this embodiment, the epitaxial stack 103′ is made of AlGaInP, the growth substrate 001 is made of GaAs and has a lattice-matched structure to facilitate epitaxial growth and improve growth quality of the epitaxial structure 103′. The first type semiconductor layer 1031′ may be one of an N-type semiconductor layer or a P-type semiconductor layer, and the second type semiconductor layer 1033′ may be the other. In this embodiment, the first type semiconductor layer 1031′ is the P-type semiconductor layer, and the second type semiconductor layer 1033′ is the N-type semiconductor layer.

In the step S102, the epitaxial stack 103′ is bonded to a transparent substrate 101. Referring to FIG. 6, after the epitaxial stack 103′ is formed (see FIG. 5), a transparent substrate 101 is provided. In this embodiment, the transparent substrate 101 is a sapphire substrate. Sapphire substrates have good transparency and stability, and may improve light extraction efficiency. Next, a bonding layer 102 is formed via deposition on a surface of the first type semiconductor layer 1031′ of the epitaxial structure 103′. In some embodiments, before depositing the bonding layer 102, the first type semiconductor layer 1031′ is patterned. Next, after depositing the bonding layer 102, a surface of the bonding layer 102 that is distal from the first type semiconductor layer 1031′ is first planarized and smoothened before being used to bond the epitaxial stack 103′ to the transparent substrate 101. Referring back to FIG. 6, after bonding the epitaxial stack 103′ to the transparent substrate 101, the growth substrate 001 is removed, thereby exposing a surface of the second type semiconductor layer 1033′.

In the step 103, the epitaxial stack 103′ is etched to form first contact electrodes 1051. After removing the growth substrate 101, a photoresist is formed on the exposed surface of the second type semiconductor layer 1033′ (photoresist is not shown in FIG. 7. The second type semiconductor layer 1033′ and the active layer 1032′ of the epitaxial stack 103′ are then etched to expose the first type semiconductor layer 1031′ and form first mesas 1050 and 1050″ (see FIGS. 1 and 7). FIG. 7 is a cross sectional view taken along line E-E of FIG. 7. Referring to FIGS. 1 and 7, the region (C) is a region of the epitaxial structure 103 above which the first electrode pad 1081 will be disposed. The first mesas 1050 (only one is shown in FIG. 7) are arranged in an array manner in the region (C). The first mesas 1050″ (only one is shown in FIGS. 1 and 7) are formed between adjacent epitaxial structures 103 (only one is shown in FIGS. 1 and 7) and are further etched to form second mesas 1054 (only one is shown in FIGS. 1 and 7). The second mesas 1054 are used as dicing lanes in later steps of the fabrication process. Next, an electrically conductive material is deposited in the first mesas 1050 to form a plurality of first contact electrodes 1051 that are respectively located in the first mesas 1050, and that are arranged in the array manner. The first contact electrodes 1051 may be made of one of Au, BeAu, AuZn, and Pt into a single-layered structure, or from a combination or combinations of the above materials into a multi-layered structure. In other embodiments, the first contact electrodes 1051 may be made of a transparent conductive material such as ITO, or IZO and may have a single-layered structure or a multi-layered structure.

Referring to FIG. 1, the region (D) is a region in the epitaxial structure 103 above which the second electrode pad 102 will be formed. Referring to FIG. 8, in order to form the fingers 1053 of the first contact electrodes 1051 in the region (D), during the etching of the epitaxial stack 103′ in step 103, channels 1050′ (only one is shown) are also formed to expose the first type semiconductor layer 1031 in the region (D). Each of the channels 1050′ extend from the region (D) towards the region (C) and is spatially communicated with a corresponding one of the first mesas 1050 in the region (C) (i.e., a nearest one). In some embodiments, an electrically conductive material is deposited in the channels 1050′ and form fingers 1053 that become electrically connected with a corresponding one of the first contact electrodes 1051 in the first mesas 1050 in the region (C).

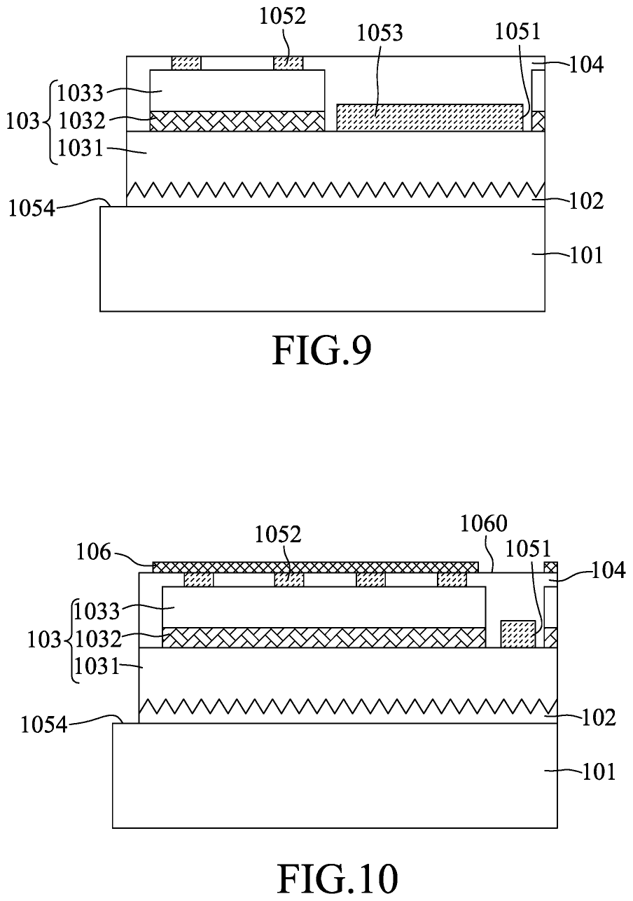

In the step S104, the second contact electrodes 1052 are formed. Referring to FIGS. 9 and 10, a transparent dielectric layer 104 is formed on areas of the epitaxial structure 103, the first contact electrodes 1051, and the fingers 1053. The transparent dielectric layer 104 covers a surface of the epitaxial structure 103, exposed areas of the second type semiconductor layer 1033, and side walls of the active layer 1032. The transparent dielectric layer 104 also fills the first mesas 1050 and the channels 1050′ and envelops the first contact electrodes 1051 and the fingers 1053, and thereby isolate the first contact electrodes 1051 from the active layer 1032 and the second type semiconductor layer 1033.

Referring to FIGS. 9 and 10, the second contact electrodes 1052 are formed and arranged in an array manner. More specifically, the transparent dielectric layer 104 is first etched to form through holes that are arranged in an array manner, and that expose the second contact electrodes 1052. In the through holes, an electrically conductive material is deposited to form the second contact electrodes 1052. The electrically conductive material may be a metal such as Au, GeAuNi, Ni, or Pt, and formed in a single layer structure, or a combination or combinations of the above materials formed in a multilayer structure. Referring to FIG. 1, in the (C) region the second contact electrodes 1052 are arranged in an array manner, and are distributed along at least one circular ring 002 that is concentric with one of the first contact electrodes 1051. The second contact electrodes 1052 in the region (D) are interspersed between the fingers 1053 in an array manner. The array arrangement of the first contact electrodes may 1051 and the second contact electrodes 1052, may on the one hand, reduce the loss of effective light emitting area due to the placement of the first contact electrodes 1051; and may on the other hand, reduce the contact area between the epitaxial structure 103 and the first and second contact electrodes 1051, 1052, and improve light emission efficiency.

In the step S105, a metallic reflection layer 106 is formed. Referring to FIG. 10, after forming the transparent dielectric layer 104 and the second contact electrodes 1052, the metallic reflection layer 106 is formed on the transparent dielectric layer 104. The metallic reflection layer 106 at least covers an area of the transparent dielectric layer 104 that is above the second type semiconductor layer 1033, and can effectively reflect light emitted from the active layer 1032. Additionally, the metallic reflection layer 106 has the benefit of facilitating the adherence of an insulating layer over side walls of the metallic reflection layer 106. The insulating layer may provide protection against oxidation or corrosion. In some embodiments, the metallic reflection layer 106 is an Ag reflector with a thickness that is no greater than 400 nm.

The metallic reflection layer 106 is electrically connected to the second type contact electrodes 1052 in the transparent dielectric layer 104 to form an electrically conducting structure. The metallic reflection layer 106 is etched to form first openings 1060 that are arranged in an array manner above the first contact electrodes 1051. The first openings 1060 are for preventing a first pad 1081 from forming an electrical connection with the metallic reflection layer 106. In some embodiments, the first openings 1060 are larger in dimension than the first mesas 1050.

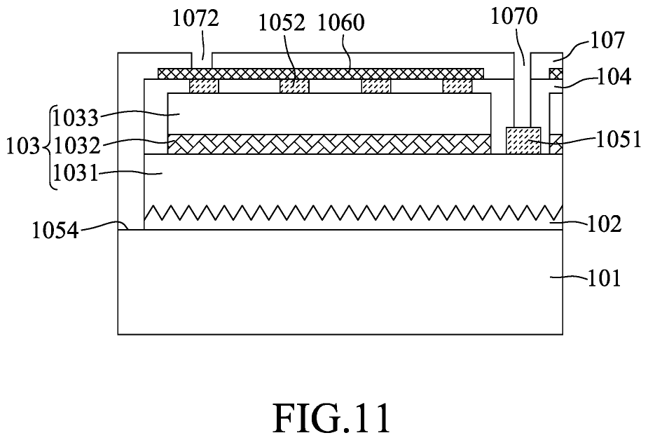

In the step S106, a first insulating layer 107 is formed. Referring to FIG. 11, a first insulating layer 107 is deposited on the structure shown in FIG. 10. The first insulating layer 107 covers side walls and a surface of the metallic reflection layer 106 and side walls of the epitaxial structure 103. The first insulating layer 107 fills the first openings 1060, and is deposited on the exposed side walls of the first type semiconductor 1031 and the transparent dielectric layer 104 to act as protection. Next, after depositing the first insulating layer 107, a patterned photoresist (not shown) is formed on the first insulating layer 107, and the insulating layer 107 is then etched. More specifically, referring to FIG. 11, the first insulating layer 107 and the transparent dielectric layer 104 are etched to expose the first contact electrodes 1051 and respectively form first through holes 1070 that correspond to each of the first contact electrode 1051, in the region (C). In the region (D), the first insulating layer 107 is etched to expose the metallic reflection layer 106, and form second through holes 1072.

In the step S107, a first pad 1081 and a second pad 1082 are formed. Referring to FIGS. 1 to 3, a metallic material is deposited on the structure seen in FIG. 11 to form the first pad 1081 and the second pad 1082. The first pad 1081 and the second pad 1082 are formed via deposition of a metallic material on the first insulating layer 107, thereby isolating the first pad 1081 from the second pad 1082. The metallic material also fills each of the first through holes 1070 and the second through holes 1072, and thereby electrically connects the first pad 1081 to the first contact electrodes 1051. The second pad 1082 is electrically connected to the metallic reflection layer 106, and then electrically connected to the second contact electrodes 1052.

In summery of the above, when the flip-chip light-emitting device 100 in the first embodiment is powered by an electric current, the current can flow through the first contact electrode 1051 and reach the first type semiconductor layer 1031. Due to the array arrangement of the first contact electrodes 1051 the current will by distributed evenly when reaching the first type semiconductor layer 1031 which improves current spreading, thereby increasing light emission efficiency.

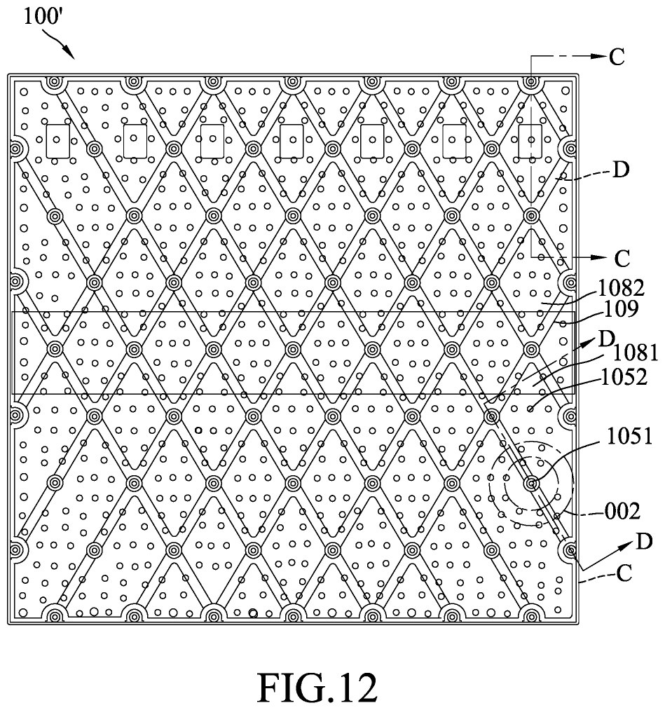

Referring to FIGS. 12 to 14, a second embodiment of the flip-chip light-emitting device 100′ according to the present disclosure includes a transparent substrate 101, an epitaxial structure 103 formed on the transparent substrate 101, a transparent dielectric layer 104 formed on the epitaxial structure 103, a metallic reflection layer 106 formed on the transparent dielectric layer 104, a first insulating layer 107 covering the metallic reflection layer 106 and side walls of the epitaxial structure 103, and an electrode pad region located on the first insulating layer 107. The epitaxial structure 103 is formed on the transparent substrate 101 and includes a first type semiconductor layer 1031, an active layer 1032, and a second type semiconductor layer 1033 sequentially stacked in a laminating direction from an upper surface of the transparent substrate 101.

The electrode pad region includes a first pad 1081 that is electrically connected to the first type semiconductor layer 1031, and a second pad 1082 that is connected to the second type semiconductor layer 1032.

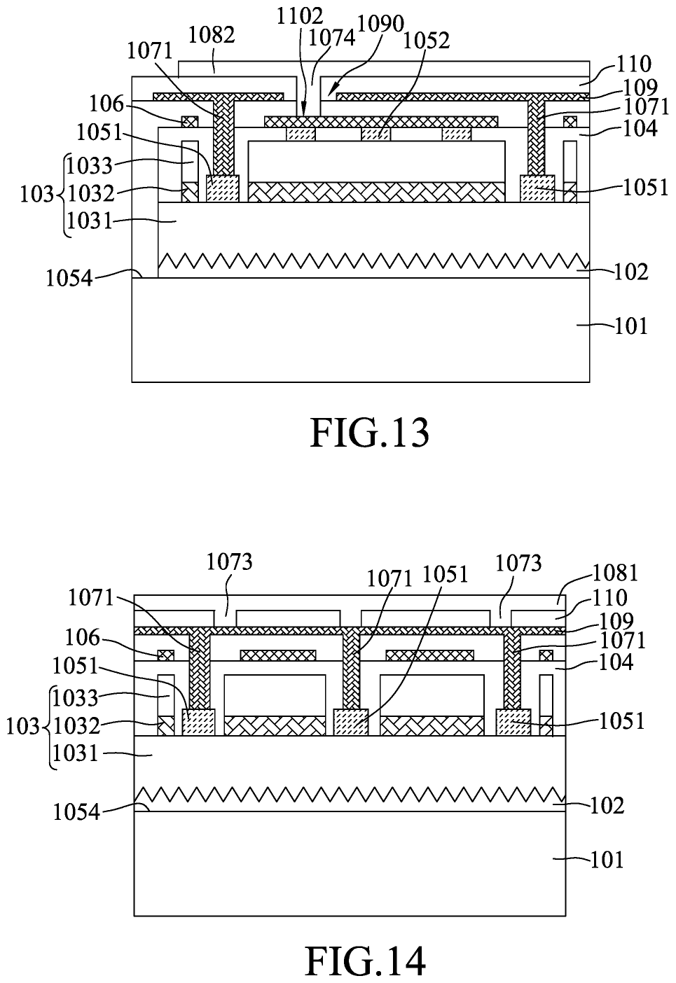

Referring to FIGS. 12 to 14, the second embodiment is similar to the first embodiment. However, the second embodiment is different from the first embodiment in that the first contact electrodes 1051 and the second contact electrodes 1052 are both arranged in an array, and that the second contact electrodes 1052 are distributed along multiple sets of concentric ring arrays. Each set of the concentric ring arrays is centered on one of the first contact electrodes 1051. Additionally, referring to FIGS. 13 and 14, in this embodiment, the flip-chip light-emitting device 100′ includes a second insulating layer 110 and a metallic mesh layer 109 is located above the first insulating layer 107. The metallic mesh layer 109 is located on the first insulating layer 107, and has a mesh structure that electrically connects with the first contact electrodes 1051. The second insulating layer 110 is disposed on the metallic mesh layer 109. The electrode pad region is disposed on the second insulating layer 110. Referring to FIG. 13, the flip-chip light-emitting device 100′ includes a plurality of conductive pillars 1071. Each of the conductive pillars 1071 is formed on a respective one of the first contact electrodes 1051 and passes through the transparent dielectric layer 104 and the first insulating layer 107. The conductive pillars 1071 electrically connect the metallic mesh layer 109 to the first contact electrodes 1051.

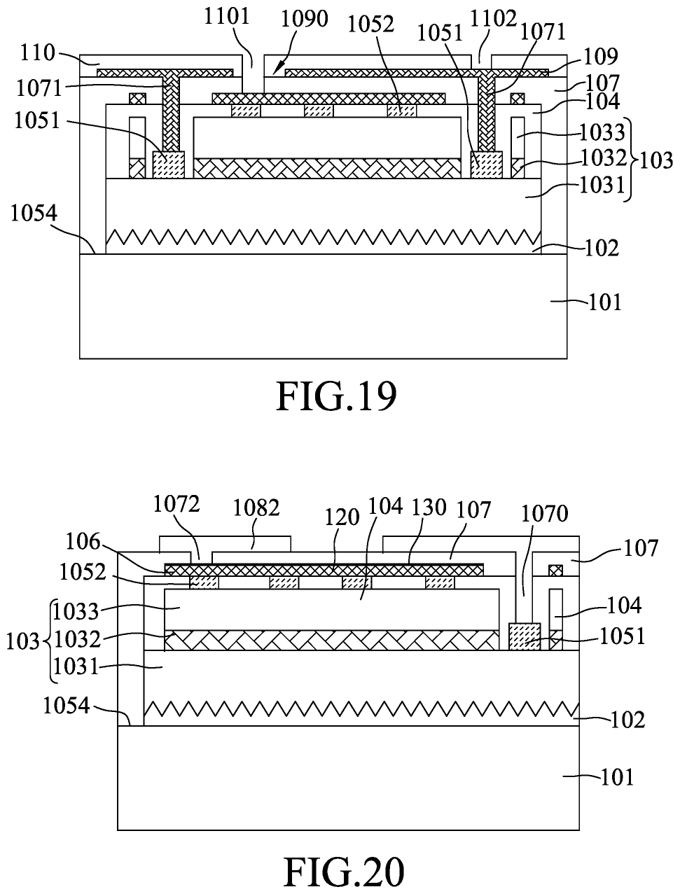

The region (C) has a plurality of third through holes 1101 (see FIG. 19) passing through the second insulating layer 110. The first pad 1081 is formed to fill the third through holes 1101 and covers the second insulating layer 110. The first pad 1081 electrically connects with the first contact electrode 1051 through the metallic mesh layer 109 and the conductive pillars 1071, and is further electrically connected with the first type semiconductor layer 1031. The region (D) has a plurality of fourth through holes 1102 (see FIG. 19) passing through the first insulating layer 107. More specifically, the fourth through holes 1102 pass through the second insulating layer 110 and the first insulating layer 107 and expose the metallic reflection layer 106. The second pad 1082 electrically connects with the metallic reflection layer 106 through the fourth through holes 1102. In some embodiments, the metallic mesh layer 109 has second openings 1090 (see FIG. 19) at areas corresponding to the fourth through holes 1102. The fourth through holes 1102 have a smaller diameter than the second openings 1090, thereby ensuring that when the second pad 1082 fills the fourth through holes 1102 in a later stage, the second pad 1082 will be electrically isolated from the metallic mesh layer 109 via the second insulating layer 110. Referring to FIG. 13, the metallic reflection layer 106 is electrically connected with the second contact electrode 1052. The second contact electrode 1052 is therefore electrically connected to the first contact electrode 1051 via the metallic reflection layer 106, and then, further electrically connected to the second type semiconductor layer 1033.

In the flip-chip light-emitting device 100′ of the second embodiment, the first contact electrodes 1051 and the second contact electrodes 1052 are arranged in an array, and the second contact electrodes 1052 are distributed along multiple sets of concentric ring arrays, each set of the concentric ring arrays is centered on one of the first contact electrodes 1051. The array arrangement of the first contact electrodes 1051, may on the one hand, reduce the loss of effective light emitting area due to the placement of the first contact electrodes 1051, and may on the other hand, reduce the contact area between the first type semiconductor layer 1031 and the first contact electrodes 1051 and improve light emission efficiency. By using the metallic mesh layer 109 that has a mesh structure to electrically connect with the first contact electrodes 1051, current spreading may be improved.

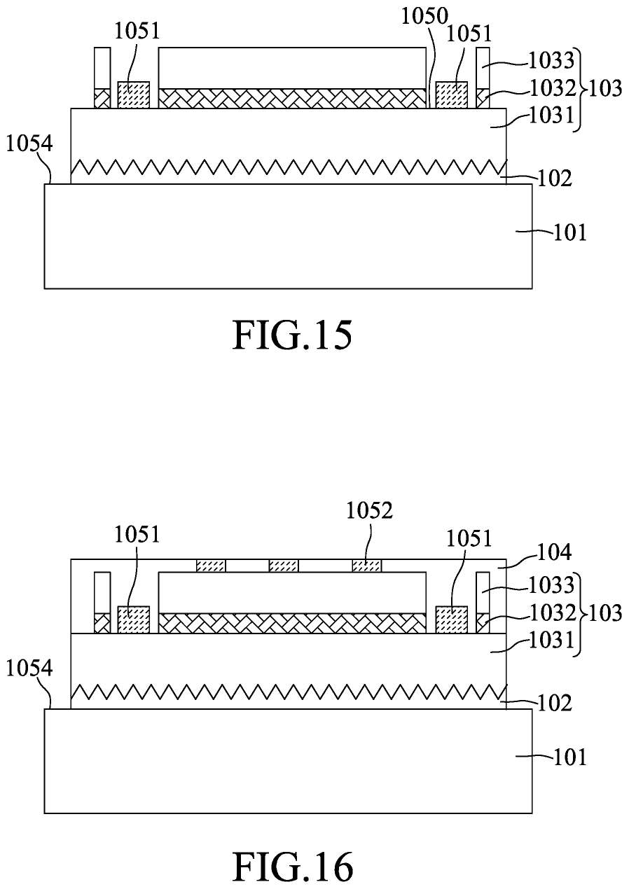

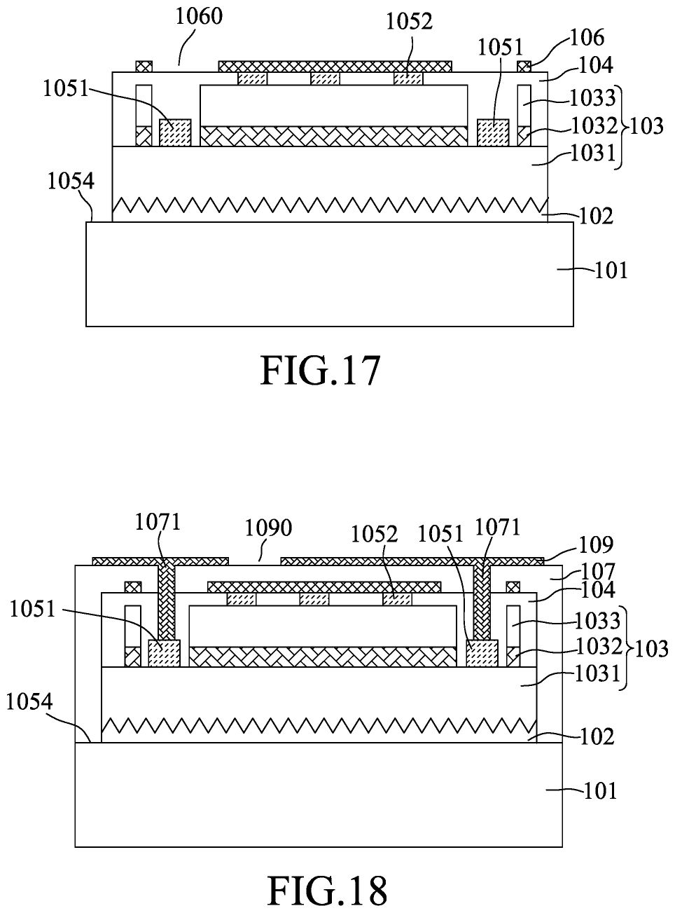

Referring to FIGS. 15 to 19, a method for making the second embodiment of the flip-chip light-emitting device 100′ is similar to the method for making the first embodiment, and only the differences will be described below. Referring to FIG. 15, the epitaxial structure 103 is etched to form the first contact electrodes 1051. A window patterned photoresist with windows arranged in an array is formed on the epitaxial structure 103, and the second type semiconductor layer 1033 and the active layer 1032 of the epitaxial structure 103 are etched through the windows to expose the first type semiconductor layer 1031 and form a plurality of first mesas 1050 arranged in an array. An electrically conductive material is deposited on each of the first mesas 1050 to form a plurality of first contact electrodes 1051 arranged in the array. Referring to FIG. 16, a transparent dielectric layer 104 is deposited on the epitaxial structure 103, the side walls of the epitaxial structure 103, and the first mesas 1050. The transparent dielectric layer covers the first contact electrodes 1051 and exposed surface and side walls of the first mesas 1050. As in the first embodiment, a second contact electrode 1052 is formed in the transparent dielectric layer 104. The second contact electrodes 1052 are arranged in an array, and distributed along multiple sets of concentric ring arrays. Each set of the concentric ring arrays is centered on one of the first contact electrodes 1051. Referring to FIG. 17, a metallic reflection layer 106 is formed on the transparent dielectric layer 104, a plurality of first openings 1060 are formed in the metallic reflection layer 106, each first opening 1060 is formed at a position corresponding to a first mesa 1050. Referring to FIG. 18, a first insulating layer 107 is formed on the metallic reflection layer 106 and the transparent dielectric layer 104. The first insulating layer 107 and the transparent dielectric layer 104 are etched to form a plurality of through holes. Each through hole is formed at a position that corresponding to a first contact electrode 1051. An electrically conductive material is deposited in each through hole to form a conductive pillar 1071. A top surface of each conductive pillar 1071 is coplanar with the top surface of the first insulating layer 107. Next, a metallic mesh layer 109 is formed on the first insulating layer 107. The metallic mesh layer 109 is disposed on the first insulating layer 107, and covers the conductive pillars 1071 to electrically connect with the conductive pillars 1071. After forming the metallic mesh layer 109, an area on the metallic mesh layer 109 that corresponds to each second contact electrode 1052 is etched to form a second opening 1090. It should be noted that because the metallic mesh layer 109 has a mesh structure that electrically connects with the conductive pillars 1071. The etching of the second openings 1090 is not strictly necessary. In some embodiments, the second openings 1090 may represent the holes in the mesh structure of the metallic mesh layer 109. In some embodiments, the conductive pillars 1071 and the metallic mesh layer 109 may be formed at the same time. More specifically, after etching the first insulating layer 107 and the transparent dielectric layer to form the through holes, a metallic material is deposited on the through hole and the first insulating layer 107 to form the conductive pillars 1071 and the metallic mesh layer 109.

Referring to FIG. 19, next, a second insulating layer 110 is formed on the metallic mesh layer 109. The second insulating layer 110 covers the metallic mesh layer 109 and exposed areas of the first insulating layer 107. Afterwards, the second insulating layer 110 is etched in the region (C) to form third through holes 1101. The third through holes 1101 pass through the second insulating layer 110 and exposes the metallic mesh layer 109. The second insulating layer 110 and the first insulating layer 107 is etched in the region (D) to form fourth through holes 1102 respectively corresponding in position to the second openings 1090. The fourth through holes 1102 pass through the second insulating layer 110 and the first insulating layer 107 to expose the metallic reflection layer 106. Subsequently a metallic material is deposited on the structure shown in FIG. 19 to respectively form the first pad 1081 and the second pad 1082. When the metallic material is deposited, the third through holes 1101 and the fourth through holes 1102 will also respectively be filled, and the first pad 1081 will be electrically connected with the metallic mesh layer 109 to thereby electrically connect with the first type semiconductor layer 1031 via the conductive pillar 1071 and the first contact electrodes 1051. The second pad 1082 will be electrically connected with the metallic reflection layer 106 and further be electrically connected with the second type semiconductor layer 1033 via the second contact electrodes 1052.

In this embodiment, electric current may flow to the first type semiconductor layer 1031 via the first contact electrodes 1051 and the metallic mesh layer 109. The array arrangement of the first contact electrodes 1051 and the second contact electrodes 1052 allows the current flow to spread evenly, improves uneven current distribution, and further ensures uniform current distribution into the first type (i.e., p-type semiconductor) semiconductor layer 1031, thereby improving light emission efficiency.

Referring to FIG. 20, a third embodiment of the flip-chip light-emitting 100″ device according to the present disclosure includes a transparent substrate 101, an epitaxial structure 103 formed on the transparent substrate 101, a transparent dielectric layer 104 formed on the epitaxial structure 103, a metallic reflection layer 106 formed on the transparent dielectric layer 104, a first insulating layer 107 covering the metallic reflection layer 106 and side walls of the epitaxial structure 103, and an electrode pad region located on the first insulating layer 107. The electrode pad region includes a first pad 1081 that is electrically connected to the first type semiconductor layer 1031, and a second pad 1082 that is connected to the second type semiconductor layer 1033.

The third embodiment is similar to the first embodiment, and only the differences will be explored in the following. Referring to FIG. 20, the flip-chip light-emitting device 100″ includes a transparent electrically conductive adhesion layer 120 located between the transparent dielectric layer 104 and the metallic reflection layer 106. The transparent electrically conductive adhesion layer 120 is distributed in a spotted manner. In some embodiments, the transparent electrically conductive adhesion layer 120 is a spotted transparent ITO layer. The transparent electrically conductive adhesion layer 120 has a thickness that is no greater than 10 nm to enhance adhesion between the transparent dielectric layer 104 and the metallic reflection layer 106. Additionally, it should be noted that the spotted distribution of the transparent electrically conductive adhesion layer 120 can reduce light absorption, increase light emission efficiency.

In some embodiments, the flip-chip light-emitting device includes a metallic adhesion layer 130 located between the metallic reflection layer 106 and the first insulating layer 107. The metallic adhesion layer 130 increases adhesion between the metallic reflection layer 106 and the first insulating layer 107, and protects the metallic reflection layer 106 from oxidation. In some embodiment, the metallic adhesion layer 130 is made of Ti, and has a thickness that is less than 40 nm.

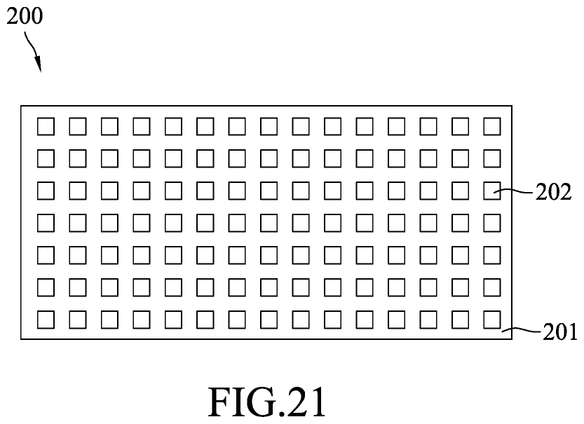

Referring to FIG. 21, a light emitting module 200 includes a circuit board 201 and multiple light emitting elements 202. The light emitting elements 202 may be the flip-chip light-emitting device 100, 100′, 100″ of the first, second or third embodiment of the disclosure.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A flip-chip light-emitting device comprising:
a transparent substrate;
an epitaxial structure formed on said transparent substrate that includes a first type semiconductor layer, an active layer, and a second type semiconductor layer sequentially stacked in a laminating direction from an upper surface of said transparent substrate;
a transparent dielectric layer formed on said upper surface of said epitaxial structure;
a plurality of first contact electrodes embedded in said transparent dielectric layer, and electrically connected to said first type semiconductor layer;
a plurality of second contact electrodes embedded in said transparent dielectric layer, and electrically connected to said second type semiconductor layer;
a metallic reflection layer formed on said transparent dielectric layer;
a first insulating layer covering said metallic reflection layer and side walls of said epitaxial structure;
an electrode pad region located on said first insulating layer, and including a first pad that is electrically connected to said first type semiconductor layer, and a second pad that is connected to said second type semiconductor layer;
wherein said second contact electrodes are arranged and said first contact electrodes are arranged in an array manner; and
wherein at least some of said second contact electrodes disposed in a region (C) perpendicularly below said first pad are distributed along at least one circular ring that is centered on one of said first contact electrodes.

2. The flip-chip light-emitting device as claimed in claim 1, wherein:
said first contact electrodes located in a region (D) perpendicularly below said second pad, are formed as a plurality of fingers, and said second contact electrodes located in said region (D) are interspersed between said fingers in an array manner;
each of said fingers is connected with a corresponding one of said first contact electrodes located in said region (C).

3. The flip-chip light-emitting device as claimed in claim 2, wherein:
said region (C) has a plurality of first through holes that pass through said transparent dielectric layer and said first insulating layer, said first pad being electrically connected to said first contact electrodes via said first through holes; and
said region (D) has a plurality of second through holes that pass through said first insulating layer, said second pad being electrically connected to said metallic reflection layer via said second through holes.

4. The flip-chip light-emitting device as claimed in claim 1, wherein said metallic reflection layer is an Ag reflector.

5. The flip-chip light-emitting device as claimed in claim 1, wherein, said second contact electrodes disposed in a region (D) perpendicularly below said second pad are distributed along multiple sets of concentric ring arrays, each set of said concentric ring arrays being centered on one of said first contact electrodes.

6. The flip-chip light-emitting device as claimed in claim 5, further comprising:
a metallic mesh layer disposed on said first insulating layer, and having a mesh structure that electrically connects with said first contact electrodes;
a second insulating layer disposed on said metallic mesh layer, said electrode pad region being disposed on said second insulating layer;
a plurality of conductive pillars, each of said conductive pillars being formed on a respective one of said first contact electrodes and passing through said transparent dielectric layer and said first insulating layer, said conductive pillars electrically connecting said metallic mesh layer to said first contact electrodes;
wherein said region (C) has a plurality of third through holes passing through said second insulating layer, and said first pad electrically connects with said metallic mesh layer through said third through holes; and
wherein said region (D) has a plurality of fourth through holes passing through said first insulating layer, said second pad electrically connecting with said metallic reflection layer through said fourth through holes.

7. The flip-chip light-emitting device as claimed in claim 1, further comprising a transparent electrically conductive adhesion layer located between said transparent dielectric layer and said metallic reflection layer, said transparent electrically conductive adhesion layer is distributed in a spotted manner.

8. The flip-chip light-emitting device as claimed in claim 7, wherein said transparent electrically conductive adhesion layer is a spotted transparent ITO layer.

9. The flip-chip light-emitting device as claimed in claim 1, wherein said flip-chip light-emitting device emits red light or infrared light.

10. The flip-chip light-emitting device as claimed in claim 1, further comprising a transparent bonding layer that bonds said epitaxial structure to said transparent substrate.

11. The flip-chip light-emitting device as claimed in claim 1, further comprising a metallic adhesion layer located between said metallic reflection layer and said first insulating layer.

12. A light emitting module comprising a circuit board, and said flip-chip light-emitting device as claimed in claim 1 being mounted on said circuit board.
